(19) United States
(12) Patent Application Publication
(10) Pub. No.: US 2025/0210585 A1
(43) Pub. Date: Jun. 26, 2025

(54) DIRECT BONDING OF SEMICONDUCTOR ELEMENTS

(71) Applicant: Adeia Semiconductor Bonding Technologies Inc., San Jose, CA (US)

(72) Inventors: Gaius Gillman FOUNTAIN, JR., Youngsville, NC (US); George Carlton HUDSON, Wendell, NC (US)

(21) Appl. No.: 18/395,347

(22) Filed: Dec. 22, 2023

(51) Int. Cl. H01L 23/00; H01L 21/02

(52) U.S. Cl. CPC H01L 24/83; H01L 21/0214; H01L 21/02274; H01L 2224/8303; H01L 2224/83359; H01L 2224/83896; H01L 2924/05042; H01L 2924/05442; H01L 2924/059

(57) ABSTRACT

In the present disclosure, a first semiconductor element of a bonded structure comprises a semiconductor-containing oxynitride bonding layer formed on a first substrate layer comprising a semiconductor material, e.g., a single crystal silicon. The semiconductor-containing oxynitride bonding layer is formed by exposing an upper surface of the first substrate layer to products of plasma containing nitrogen and oxygen at controlled plasma conditions. The second semiconductor element of the bonded structure may have a second substrate layer comprising a semiconductor material, e.g., a single crystal silicon, and a semiconductor-containing oxynitride bonding layer formed over the second substrate layer in the same way as the first semiconductor element. In some embodiments, the second semiconductor element may have a bonding layer comprising a dielectric material. After initial direct bonding of the first and second semiconductor elements, the bonded structure may go through an annealing process to strengthen the bonding.

### BACKGROUND

### Field

The field relates to direct bonding of semiconductor elements.

### Description of the Related Art

The microelectronics industry has experienced tremendous growth over the past decades. However, the demand in the market for ever higher input/output (I/O) density and faster connection between chips has increased. This demand has driven integrated circuit (IC) system designs into three-dimensional (3D) architectures. Solder bumps and micro-bumps can provide vertical interconnects between chips by using small metal bumps on dies or wafers as one form of packaging. Hybrid bonding can provide a solution for superior density of interconnect features.

Hybrid bonding, such as the DBI® technology commercially available from Adeia of San Jose, CA, avoids the use of metal bumps, and instead bonds dies or wafers in packages using direct dielectric-to-dielectric and metal-to-metal, e.g., copper-to-copper, conductive feature bonding. In the bonding layer of each bonding element, conductive features, such as metal contact pads, are embedded in the dielectric material. The hybrid bonding surface can be planarized by chemical mechanical polishing (CMP) and cleaned to remove particles and contaminants. Plasma activation can create active sites on the dielectric of the hybrid bonding surface of at least one of the two elements to be bonded. The two bonding elements are aligned as they are brought together with bonding equipment and the bonding surfaces bond to each other without an intervening adhesive. The dielectric-to-dielectric bonding can be processed at room temperature. An annealing process at an elevated temperature can aid in bonding aligned conductive features, and can also strengthen bonds between the dielectric materials.

### BRIEF DESCRIPTION OF THE DRAWINGS

Specific implementations will now be described with reference to the following drawings, which are provided by way of example, and not limitation.

FIG. 1 is a schematic cross-sectional view of two microelectronic elements configured to be hybrid bonded together.

FIG. 2 is a schematic cross-sectional view of a bonded structure comprising the two microelectronic elements shown in FIG. 1.

FIGS. 3-5 are Confocal Scanning Acoustic Microscopy (CSAM) images of bonded wafers including silicon in bonding layers directly bonded using a conventional method at different annealing conditions.

FIG. 6 is a schematic cross-sectional view illustrating a semiconductor element having a thin layer of silicon oxynitride formed on a substrate layer that includes silicon therein.

FIG. 7 is a process flowchart illustrating a process for preparing and bonding two elements that have the same base substrates and bonding layers.

FIG. 8 is a schematic cross-sectional view illustrating two microelectronic elements of FIG. 6 configured to be direct bonded together.

FIG. 9 is a schematic cross-sectional view illustrating a bonded structure comprising two semiconductor elements of FIG. 8 after bonding.

FIG. 10 is a schematic cross-sectional view illustrating a microelectronic element having a base substrate layer and a microelectronic element of FIG. 6 configured to be directly bonded together.

FIG. 11 is a schematic cross-sectional view illustrating a bonded structure comprising two semiconductor elements of FIG. 10 after bonding.

FIG. 12 is a schematic cross-sectional view illustrating a microelectronic element having a dielectric bonding layer and a microelectronic element of FIG. 6 configured to be directly bonded together.

FIG. 13 is a schematic cross-sectional view illustrating a bonded structure comprising two semiconductor elements of FIG. 12 after bonding.

FIG. 14 is a process flowchart illustrating a process for preparing and bonding the two microelectronic elements of FIG. 13 to form the bonded structure of FIG. 13.

FIGS. 15-17 are CSAM images of bonded wafers of FIG. 5 after annealed at different anncaling conditions.

### DETAILED DESCRIPTION

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

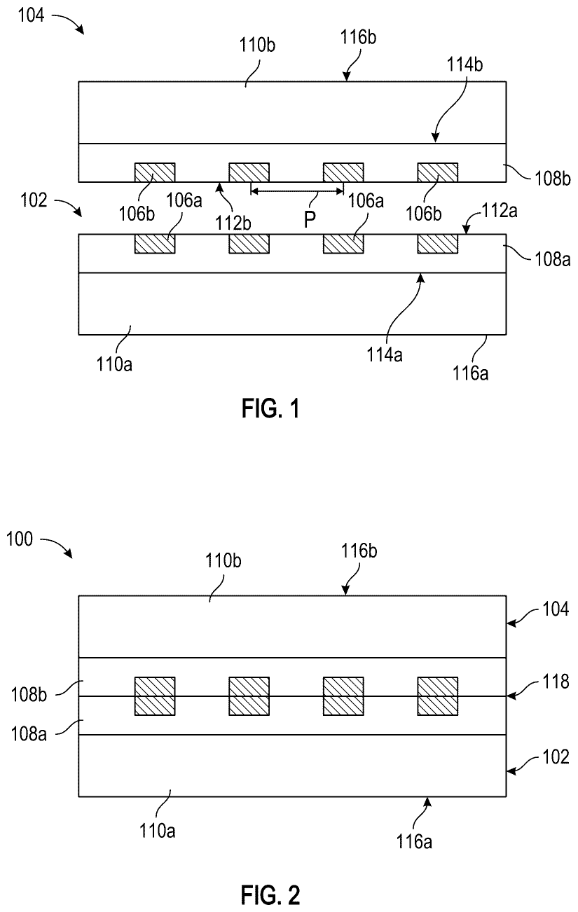

FIGS. 1 and 2 schematically illustrate cross-sectional side views of first and second elements 102, 104 prior to and after, respectively, a process for forming a directly bonded structure, and more particularly a hybrid bonded structure, according to some embodiments. In FIG. 2, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Årms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1 prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

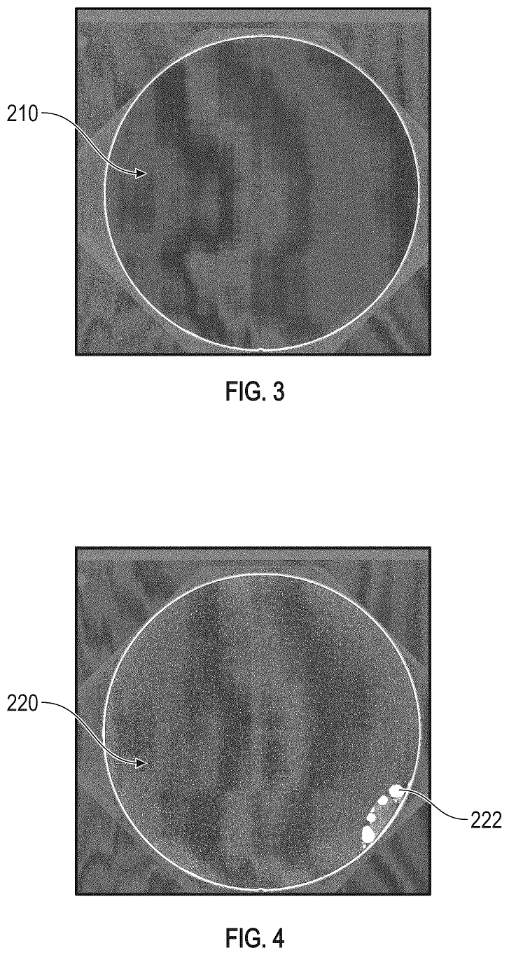

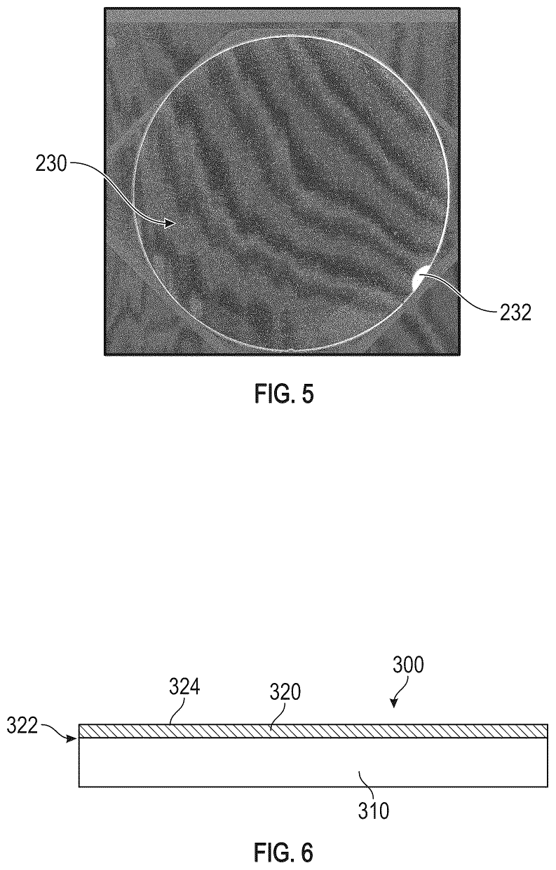

FIGS. 3-5 show Confocal Scanning Acoustic Microscopy (CSAM) images of bonded wafers or structures. After initial bonding the bonded wafers or structures are annealed. FIG. 3 shows a CSAM image of a bonded wafers 210 after annealing at 150° C. for 15 minutes; FIG. 4 shows a CSAM image of a bonded wafers 220 after annealing at 200° C. for 60 minutes; FIG. 5 shows a CSAM image of a bonded wafers 230 after annealing at 300° C. for 60 minutes. Prior to bonding the bonding surfaces for wafers to be bonded as shown in FIGS. 3-5 may be activated at room temperature to form a thin layer of non-ideal native oxide. Tests revealed that the bonded wafers for all three cases have relatively lower strength. It can be clearly seen in FIGS. 4 and 5 that large voids or bubbles 222, 232 are formed at the edges of the bonding interfaces after annealing. This means that voids in the interface can form when the annealing temperature is 200° C. or higher. Micro voids that are not visible in the CSAM images may also exist. These voids, including the visible voids, such as the voids 222 and 232 shown in FIGS. 4 and 5, and the invisible micro voids (not visible in FIGS. 4 and 5), can compromise the integrity of the bonded interface and cause low yield. Especially when a hermetic seal at the interface is important, the type of voids may cause leaking failures or long term reliability problems.

The present disclosure relates to a new process for preparing and direct bonding a first microelectronic element (e.g. semiconductor element) and a second microelectronic element (e.g., semiconductor element) together and the structure formed therefrom. Each of the first and second semiconductor elements can be a wafer, a device die, or any other type of semiconductor element. At least one of the first and second semiconductor elements has a base substrate comprising a single crystal surface, e.g., a single crystal silicon material. For example, the first semiconductor element may have a base substrate layer comprising silicon, e.g., single crystal silicon. In other embodiments, other types of semiconductor materials may be used.

Before bonding, the first and second elements may be prepared by planarizing the upper surfaces to a high degree of smoothness, e.g., by CMP, as explained above. Then the first and second elements may be cleaned, so that the bonding surfaces of the elements are sufficiently flat, smooth, and free of debris and contaminants.

In FIG. 6, a cross-sectional view of a first semiconductor element 300 having a base substrate layer 310 comprising silicon has gone through a CMP treatment to planarize an upper surface 322. The base substrate layer 310 may be a layer of a silicon substrate or a substrate comprising a semiconductor material forming a semiconductor surface. A semiconductor-containing oxynitride bonding layer 320 is directly formed on an upper semiconductor surface of the bas substrate layer 310. The process flow of treating the upper surface 322 of the semiconductor element 300 to form the bonding layer 320 comprising a semiconductor-containing oxynitride material, and bonding the first semiconductor element 300 to another element are described in the subsequent paragraphs.

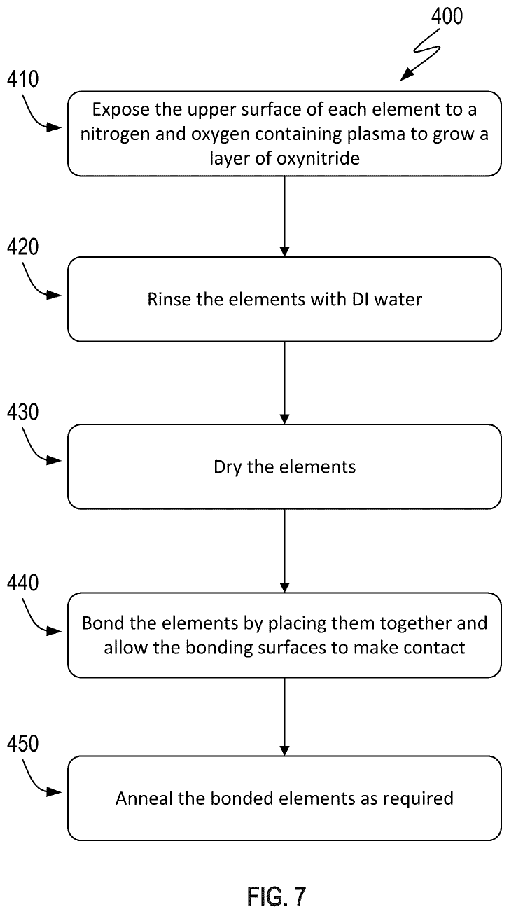

Referring to FIG. 7, a method 400 is schematically illustrated for preparing and bonding two elements that have the base substrates and bonding layers formed thereon. For example, each of the two elements involved in the process flowchart starts with a base substrate comprising silicon or another type of semiconductor material. In some embodiments, the base substrates of the two elements can comprise different types of semiconductor materials. For example, the first element has a base substrate comprising silicon, and the second element has a base substrate comprising germanium. The base substrate layer for each of the two elements is a bare substrate layer, e.g., bare single crystal silicon without any deposited dielectrics thereon. In some embodiments, there may be no additional layer formed or deposited on the base substrate before the plasma step, e.g., no additional layer deposited by chemical vapor deposition (CVD), atomic layer deposition (ALD), or other deposition processes.

A first step 410 of the method 400 comprises exposing the upper surface of each element to be bonded to at least one nitrogen and oxygen containing plasma to grow a thin layer of semiconductor-containing oxynitride (e.g., silicon oxynitride). In various embodiments, for example, the nitrogen and oxygen plasma products can comprise products of a single plasma process (e.g., a process that exposes the substrate simultaneously to oxygen and nitrogen). In other embodiments, the nitrogen and oxygen products can comprise products of multiple (e.g., sequential) plasma processes. Each of the elements involved in the process flowchart 400 may have a cross-sectional structure that is the same as or generally similar to that of the semiconductor element 300 described with respect to FIG. 6, e.g., having a base substrate layer 310 with the upper surface 322. To form a bonding layer 320 over the upper surface 322, the semiconductor element 300 may be placed in a plasma chamber and be exposed to products of a plasma containing nitrogen and oxygen at elevated temperature and controlled pressure. In other embodiments, the semiconductor element 300 may be exposed to a nitrogen containing plasma followed by an oxygen containing plasma, or vice versa. Consequently, the semiconductor-containing oxynitride is directly grown through oxidization and nitridation from the upper surface of the base substrate layer (e.g., grown directly from the silicon surface). Atom level diffusion will ensure that nitrogen and oxygen will come together and react to form semiconductor-containing oxynitride. In various embodiments, the layer of semiconductor-containing oxynitride is directly grown on the upper semiconductor containing surface (e.g., silicon) of the base substrate layer 310 of the semiconductor element 300. Accordingly, the semiconductor-containing oxynitride layer can be provided directly on so as to contact the base substrate layer 310 (e.g., silicon) of the semiconductor element 300. The plasma treatment process may employ in situ or remote plasma systems. For an in situ plasma system, a delivery system (e.g., showerhead) may supply a gas containing nitrogen and/or oxygen into the plasma chamber in which the semiconductor element 300 is held for in situ plasma exposure. For a remote plasma system, the delivery system may feed a plasma generated remotely and deliver into the chamber. In either technique the plasma ambient that the semiconductor element 300 is exposed to comprises products of plasma produced from a nitrogen (N₂) and/or oxygen (O₂) containing gas. The products of plasma can comprise reactive species of oxygen and/or nitrogen, such as oxygen ions (0²⁻), monatomic neutral oxygen (O), nitrogen ions (N³⁻), monatomic neutral nitrogen (N), and chemical compound species formed by nitrogen and oxygen, including reactive ionic compounds.

In some embodiments, the upper surface of the substrate layer 310 can be cleaned to remove any native oxide and/or native nitride residue that are formed by, for example, exposing the silicon surface to the atmosphere or air, before formation of the silicon oxynitride bonding layer. In some embodiments, the bonding layer 320 can be formed without intervening exposure to air or atmosphere. In some embodiments, a thin layer of native oxide and/or native nitride may be formed on the upper surface of the substrate layer prior to the nitrogen and oxygen containing plasma treatment, for example, after the substrate layer is exposed in air. During the plasma process, deposition of oxygen and nitrogen will continue from the thin layer of native oxide and/or native nitride. Further, atom level diffusion ensures that silicon from the substrate layer migrates through the newly formed bonding layer 320 to further grow the semiconductor-containing oxynitride.

Without being limited by theory, in some embodiments, chemical bonds of the silicon atoms at the upper surface 322 of the base substrate layer 310 may be broken by the reactive species of the products of plasma formed by the nitrogen and/or oxygen containing gas. As such the upper surface 322 of the bonding layer 320 can be activated. The broken chemical bonds of the silicon atoms at the upper surface 322 may react with and link to the reactive species of oxygen and nitrogen or their intermediate reactive chemical compounds in the products of plasma to form a semiconductor-containing oxynitride, e.g., silicon oxynitride (Si₂N₂O). The upper surface (e.g., the entire upper surface) of the base substrate layer 310 can be covered by the oxynitride compound, and a renewed upper bonding surface is formed. The renewed upper surface 324 may be activated by the reactive species of the products of plasma again, and then a new layer of oxynitride is grown. During the process, silicon atoms may diffuse from the substrate layer into the layer of oxynitride and to the upper surface. Therefore, the formed oxynitride layer may have a composition that can be expressed as SiNxOy. However, during the plasma process, the upper surface of the semiconductor element 300 may attract more or much more amount of oxygen than nitrogen to be deposited to and grow the on the bonding layer 320, which comprises semiconductor-containing oxynitride, although the plasma may contain more or much more nitrogen than oxygen, as described above. On the other hand, the silicon content is the highest deep in the substrate layer 310, and decreases in a direction from deep inside the substrate layer 310 toward the upper surface 324 of the semiconductor element 300. In some embodiments, the products of plasma may contain other chemical elements or compounds, e.g., carbon, hydrogen, etc. As such, the formed bonding layer comprising oxynitride may additionally comprise these chemical elements or compounds in addition to SiNxOy. Consequently, the initially formed oxynitride including silicon and other elements may continuously grow under the plasma condition to form the thin bonding layer 320 with an upper bonding surface 324, as shown in FIG. 6. Since the exposed silicon atoms at the initial upper surface 322 are part of a silicon crystal lattice in the base substrate layer 310, the formed bonding layer 320 is therefore tightly connected to the base substrate layer 310 through covalent chemical bonds which can exhibit high bonding strength.

In some embodiments, a cyclic electric voltage, e.g. an alternating current (AC) voltage, may be applied in the plasma chamber, for example, with the semiconductor element 300 as an electrode. In this way, the charged ionic elements and compounds may be driven by the electrical field developed by the cyclic electric voltage to move toward and collide on the upper surface of the semiconductor element or move away from the upper surface depending on the direction of the voltage applied at the instant. Under the cyclic electric voltage, the ionic elements and compounds may collide on the upper surface of the semiconductor element again and again until they are bonded to the upper surface. As such, the growing speed of the bonding layer 320 is enhanced.

In some embodiments, an in situ plasma system is employed in the bonding layer forming process 410 for forming the bonding layer 320. In some embodiments, the plasma chamber may be kept at a temperature of about 175° C. and at a pressure of about 1 Torr for about 1 minute. The plasma temperature can be controlled in the range of 100° C.-300° C., e.g., 120° C.-250° C., 150° C.-200° C. Beneficially, the plasma temperature can be less than 200° C. to achieve adequate bond strength and improved yield. The plasma pressure can be in the range of 0.5 Torr-2 Torr, e.g., 0.8 Torr-1.5 Torr, 0.9 Torr-1.2 Torr. The plasma duration can be in the range of 0.5 minutes-2 minutes, e.g., 0.5 minutes-1.5 minutes, 0.8 minutes-1.2 minutes.

The flow rate of the nitrogen and oxygen containing gas supplied by the delivery system into the plasma chamber can comprise about 100 sccm nitrogen gas and about 20 sccm oxygen gas in some embodiments, although the ratio of nitrogen to oxygen gas flow rates can range from 1:1 to 10:1. For example, the flow rate of the nitrogen can be in the range of 50 sccm-200 sccm, the flow rate of oxygen can be in the range of 10 sccm-50 sccm, and the flow rate ratio falls between 1:1 to 10:1. An electrical power supply for ignition of plasma and causing kinetical movement to the plasma ions may be about 100 W at a cycling frequency of about 500 KHz. The electrical power supply can be in the range of 50 W-200 W, with frequency ranging from 40 KHz to 1 MHz, e.g., 80 W at 800 KHz, 150 W at 50 KHz, 100 W at 200 KHz, 200 W at 400 KHz. The gas flow rate and the power supply requirements may correlate to the surface area of the semiconductor element involved. For example, the selection of nitrogen flow rate of 100 sccm, oxygen flow rate of 20 sccm, and power supply of 100 W at 500 KHz may be suitable for a 12 inch wafer. There may also exist a relationship between the power supply frequency and the plasma pressure. For example, a lower frequency may be accomplished by a higher pressure.

In some embodiments, a thickness of the bonding layer 320 may be controlled by monitoring the parameters of the bonding layer forming process 410 as described above, e.g., temperature, pressure, flow rate, time, and power supply parameters. For example, the thickness of the bonding layer 320 may be controlled to be in the range of 0.5 nm-10 nm, e.g., 1 nm-10 nm, 2 nm-6 nm, 4 nm-8 nm, 3 nm-7 nm.

As shown in FIG. 7, after the bonding layer forming method 410, the semiconductor elements to be bonded may go through a cleaning step 420, where the elements may be rinsed with deionized (DI) water. Then elements may go through a drying step 430, e.g., by spin drying with lamp heating for about 6 minutes, e.g., 2 minutes-10 minutes, 4 minutes-8 minutes, followed by drying without heating for about 2 more minutes e.g., 1 minute-3 minutes, 1.5 minutes-2.5 minutes.

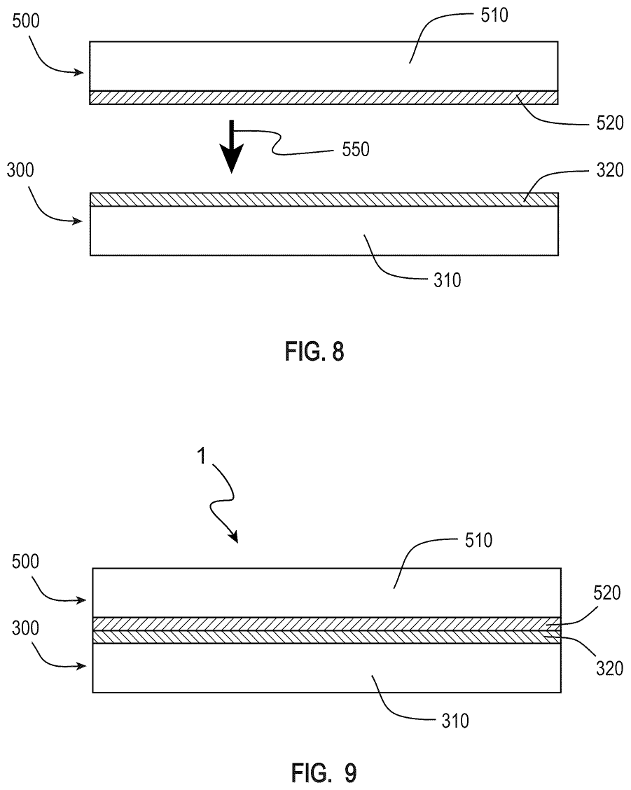

The two elements may be placed together, allowing the bonding layer of one element to face the bonding layer of the other element to be bonded, as shown in a bonding step 440 in FIG. 7. As illustrated in the cross-sectional view of FIG. 8, a first semiconductor element 300 and a second semiconductor element 500 may have the same or generally similar structures. For example, the first semiconductor element 300 has a base substrate layer 310 comprising silicon and a bonding layer 320 comprising a semiconductor-containing oxynitride, where the bonding layer 320 is disposed on the base substrate layer 310, as described with respect to FIG. 6 above. Likewise, the second semiconductor element 500 has a base substrate layer 510 comprising silicon and a bonding layer 520 comprising a semiconductor-containing oxynitride, where the bonding layer 520 is disposed on the base substrate layer 510. In other embodiments, either the first semiconductor element 300 or the second semiconductor element 500, or each, may have a base substrate layer comprising a non-silicon semiconductor substrate and a bonding layer comprising a semiconductor-containing oxynitride.

The first and second semiconductor elements 300, 500 may be held with bonding equipment, allowing the first semiconductor element 300 be placed with the bonding layer 320 facing up and the second semiconductor element 500 disposed above the first semiconductor element 300 and with the bonding layer 520 facing down and toward the bonding layer 320 of the first semiconductor element 300. The second semiconductor element 500 can be controlled to move toward the first semiconductor element 300 along a direction 550, allowing the bonding surface of the second semiconductor element 500 to be in direct contact with the bonding surface of the first semiconductor 300 without any extra layer (e.g., adhesive layer) between the bonding surfaces, forming a bonded structure 1, as shown in FIG. 9. The bonding process 440 may be conducted at room temperature, and only with a slight pressure exerted at the center portion of the second semiconductor element 500, for the two elements to be in contact to form the bonded structure 1. Some chemical bonds, e.g., covalent bonds, may form across the bonding interface due to the open bonds at the activated bonding surface of the bonding layer.

In some embodiments, after the initial bonding process 440, the direct bonded structure 1 may be annealed at an elevated temperature for a duration of time to increase the integrity and strength of the direct bonding. The bonding temperature may be in the range of 100° C.-300° C., e.g., 150° C.-250°, or 175°-200° C. The bonding duration may be in the range of 10 minutes to 1 hours, e.g., 15 minutes to 30 minutes, 20 minutes to 40 minutes. The annealing process 440 may be carried out in an annealing oven, or may be a rapid thermal (RT) process.

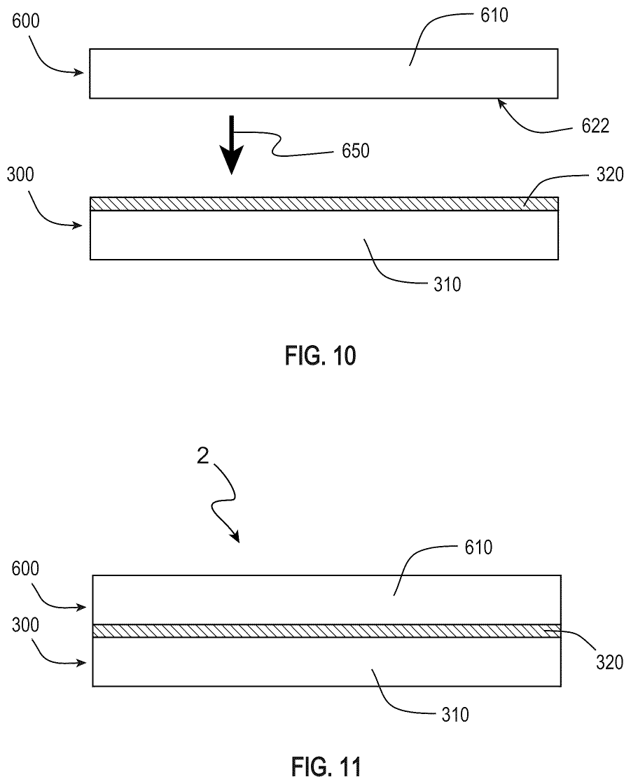

In some embodiments, only one of the two elements may undergo the process of FIG. 7 to form the oxynitride bonding layer 320. For example, as shown in FIGS. 10 and 11, the first semiconductor element 300 may be the same as in FIGS. 8 and 9, including a bonding layer 320 that comprises oxynitride, but second semiconductor element 600 comprises a base substrate layer 610 without a bonding layer disposed on an upper surface 622. The upper surface 622 is only polished for bonding but not activated, e.g., by a plasma process. In FIG. 10, the second semiconductor element 600 is disposed above the first semiconductor element 300, and is moved in a direction 650 to make contact with the first semiconductor element 300 for forming a direct bonded structure 2, as shown in FIG. 11. The initial bonding process may be conducted at room temperature. Similar to the second semiconductor element 500 in FIGS. 8 and 9, the second semiconductor element 600 in FIGS. 10 and 11 may be activated and cleaned before bonding. Subsequently, the bonded structure 2 may be annealed at an elevated temperature for a duration of time to increase the bonding integrity and strength.

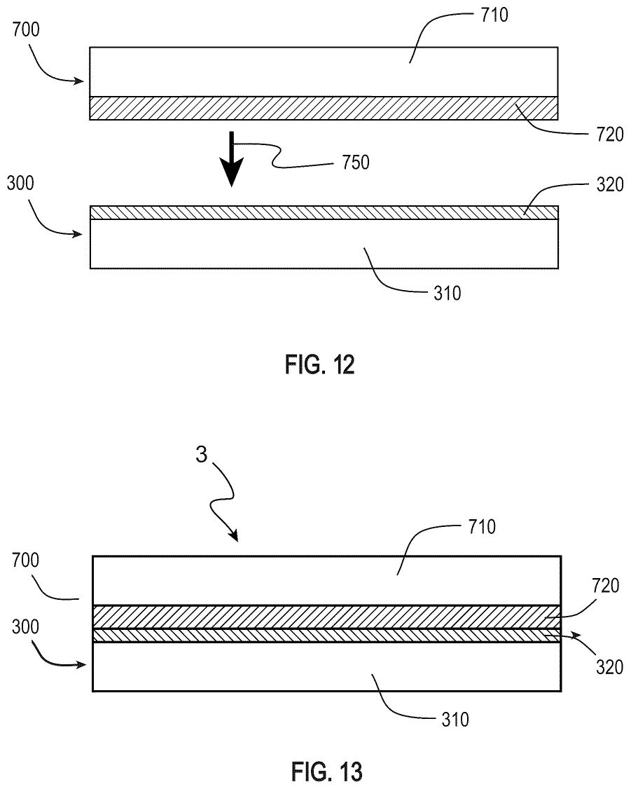

In some embodiments, one of the two elements of the bonded structure may have a bonding layer that comprises a semiconductor-containing oxynitride and the other element of the bonded structure may have a bonding layer with a non-conductive or dielectric material that is deposited before plasma activation. In FIGS. 12 and 13, a second semiconductor element 700 has a dielectric bonding layer 720 disposed on a base substrate layer 710. In some embodiments, the dielectric bonding layer 720 may include embedded conductive contact features. The dielectric bonding layer 720 may comprise inorganic dielectric materials, e.g., a dielectric material such as silicon oxide, silicon nitride, silicon oxynitride, silicon carbide, silicon oxycarbonitride, low K dielectric materials, SiCOH dielectrics, silicon carbonitride, or diamond-like carbon. A thickness of the dielectric bonding layer 720 can be significantly thicker than the bonding layer 320 of the first element 300. For example, the thickness of the dielectric bonding layer 720 is 0.1 μm-25 μm; e.g., 1 μm-20 μm, 2 μm-15 μm, 3 μm-10 μm. The second semiconductor element 700 is disposed a above the first semiconductor element 300, with the bonding layer 720 facing the first semiconductor element 300 below, or vice versa.

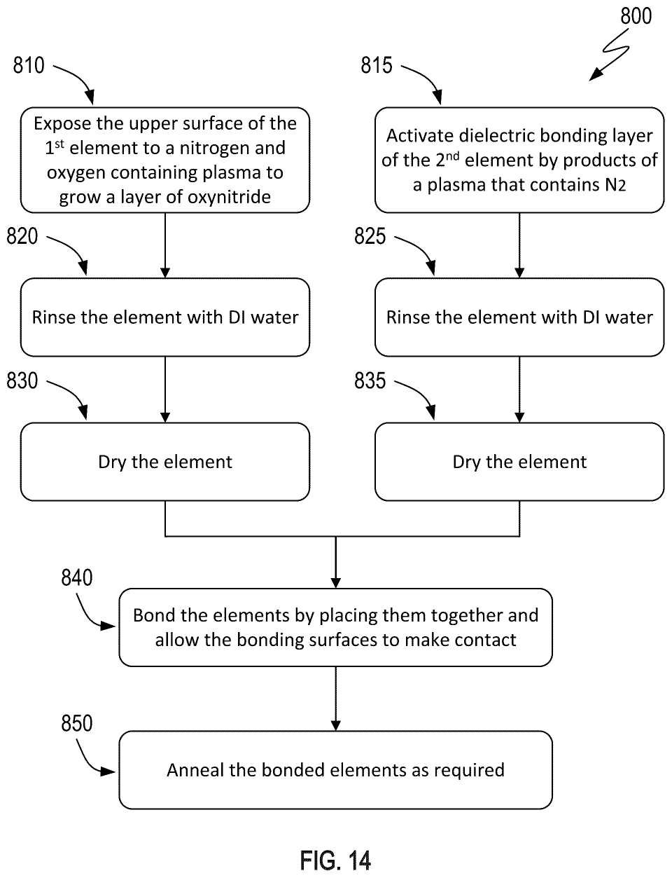

FIG. 14 is a process flow chart 800 to illustrate the process steps to prepare and make a direct bonded structure 3 shown in FIG. 13. The process steps for forming the first semiconductor element 300 may be the same as or generally similar to the method described with respect to the first semiconductor element 300 in the process flowchart 400 of FIG. 7. For example, the first semiconductor element 300 may undergo a bonding layer forming process 810 by growing a layer of oxynitride under at least one reactive nitrogen and oxygen containing plasma or sequential reactive nitrogen plasma and reactive oxygen containing plasma, followed by a cleaning process 820 and a drying process 830. In various embodiments, for example, the nitrogen and oxygen products can comprise products of a single plasma process (e.g., a process that exposes the substrate simultaneously to oxygen and nitrogen). In other embodiments, the nitrogen and oxygen products can comprise products of multiple (e.g., sequential) plasma processes. As explained above, a thin bonding semiconductor-containing oxynitride layer 320 can be formed on the base substrate 310. Meanwhile, the second semiconductor element 700 is provided with a dielectric layer 720 as shown in FIG. 12 before activation. In an activating process 815, the bonding surface of the bonding layer 720 is activated by exposing the surface to an activation plasma, e.g., a nitrogen containing plasma, e.g., for embodiments in which the dielectric layer 720 comprises silicon oxide. The conditions for the activation process 815 may be similar to the bonding layer forming process 810. For example, the plasma chamber may be kept at a temperature of about 175° C., e.g., in the range of 100° C.-300° C., 120° C.-250°, or 150°-200°, and at a pressure of about 1 Torr, e.g., in the range of 0.5 Torr-2 Torr, e.g., 0.8 Torr-1.5 Torr, or 0.9 Torr-1.2 Torr, for about 1 minute, e.g., in the range of 0.5 minutes-2 minutes, e.g., 0.5 minutes-1.5 minutes, 0.8 minutes-1.2 minutes. The electrical power supply may be in the range of 50 W-200 W, with frequency ranging from 40 KHz to 1 MHz, e.g., 80 W at 800 KHz, 150 W at 50 KHz, 100 W at 200 KHz, or 200 W at 400 KHz. The flow rate of the nitrogen containing gas supplied into the plasma chamber may be about 100 sccm, e.g., 50 sccm-200 sccm, 70 sccm-150 sccm, or 90 sccm-120 sccm. The activation conditions described herein may be suitable for a 12 inch wafer. According to the process flowchart 800, after the activation process 815, the second semiconductor element 700 may go through a cleaning process 825, where the element is rinsed with deionized (DI) water and a drying process 835, e.g., by spin drying with lamp heating for about 6 minutes, followed by drying without heating for about 2 more minutes, to ensure that the bonding surface of the second semiconductor element 700 is smooth, dry, and free of debris.

The first semiconductor element 300 and the second semiconductor element 700 can be brought together to be bonded, as shown in FIG. 12 and according to the initial bonding process 840 of FIG. 14. The second semiconductor element 700 is moved along a bonding direction 750 so that bonding surface of the bonding layer 720 of the second semiconductor element 700 makes direct contact with the bonding surface 320 of the first semiconductor element 300 to form the direct bonded structure 3, as shown in in FIG. 13. After that, the bonded structure 3 may go through an annealing process 850 at an elevated temperature for a duration of time to increase the integrity and strength of the direct bonding. As described with respect to the annealing process 450, the bonding temperature may be in the range of 100° C.-300° C., e.g., 150° C.-250°, or 175°-200° C. The bonding duration may be in the range of 10 minutes-1 hours, e.g., 15 minutes-30 minutes, or 20 minutes-40 minutes.

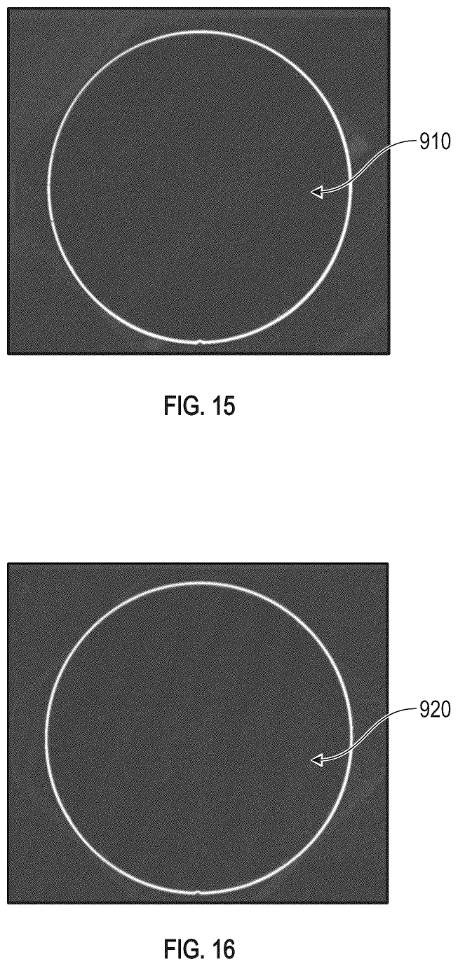

FIG. 15 shows a CSAM image of a bonded structure 910 after annealing at 150° C. for 15 minutes. The bonded structure 910 comprises two bonded wafers shown by the circle in white line, and may have a configuration of the bonded structure 1 of FIG. 9 described above, e.g., comprising two elements directly bonded together, with each element having an oxynitride bonding layer. It can be seen in FIG. 15 that the bonding is uniform and without voids across the entire bonding area bounded by the white line circle. Testing has demonstrated that after annealing a bonding strength of the bonded structure 910 is above 2000 mJ/m2, which is sufficiently strong bond to provide adequate yield.

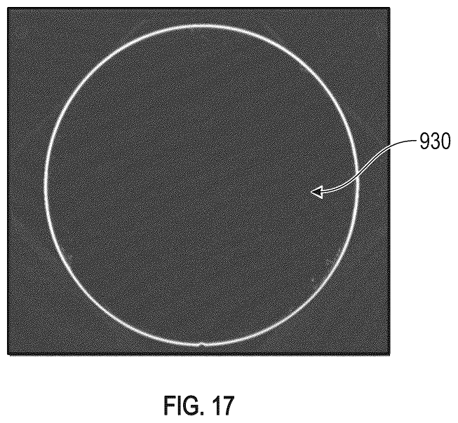

Additional tests have been conducted for bonded structures having the structures as the bonded the structure 910 but annealed at different conditions, e.g., different annealing temperatures and time durations. FIG. 16 shows a CSAM image of a bonded structure 920 after annealing at 200° C. for 30 minutes; FIG. 17 shows a CSAM image of a bonded structure 930 after annealing at 250° C. for 30 minutes. It can be seen in FIGS. 16 and 17 that uniform bonding without voids are achieved after annealing at 200° C. or 250° C. for 30 minutes. Annealing at higher temperature and for longer duration can provide higher bonding strength. Therefore, the bonding strength of the bonded 920 shown in FIG. 16 may be higher than that of the bonded structure 510 shown in FIG. 15, and the bonding strength of the bonded 930 shown in FIG. 17 may be higher than that of the bonded structure 910 shown in FIG. 15 and the bonded structure 920 shown in FIG. 16.

Comparing to the bonded wafers 210, 220, 230 bonded by conventional means shown in FIGS. 3-5, the bonded structures 910, 920, 930 comprising an oxynitride layer between the bonded elements are apparently advantageous in terms of bonding strength and integrity.

In one aspect of the disclosure, a method for forming a bonding layer on an upper surface of a semiconductor substrate comprises exposing the upper surface to products of at least one plasma containing nitrogen and/or oxygen to form a semiconductor-containing oxynitride layer on the upper surface, and preparing the upper surface for direct bonding to a semiconductor element. The preparing the upper surface comprises planarizing the upper surface. In some embodiments, the semiconductor substrate comprises bare silicon, and the semiconductor-containing oxynitride layer comprises silicon oxynitride.

In some embodiments, exposing the upper surface of the semiconductor substrate to products of a plasma comprises exposing the upper surface to products of a remote plasma system. In some embodiments, exposing the upper surface of the semiconductor substrate to products of a plasma comprising exposing the upper surface to products of an in situ plasma system.

In some embodiments, exposing the upper surface of the semiconductor substrate to products of a plasma comprises flowing the products of a plasma containing nitrogen and oxygen over the upper surface at a flow rate of about 50 sccm to 200 sccm nitrogen and about 10 sccm to 50 sccm oxygen, where a ratio of nitrogen flow rate to oxygen flow rate ranges from 1:1 to 10:1.

In some embodiments, exposing the upper surface of the semiconductor substrate to products of a plasma comprises exposing the upper surface at a temperature in the range of 100° C.-300° C. In some embodiments, the temperature range is 150° C.-200° C.

In some embodiments, exposing the upper surface of the semiconductor substrate to products of a plasma comprises performing the plasma process at a pressure in the range of 0.5-2 Torr.

In some embodiments, exposing the upper surface of the semiconductor substrate to products of a plasma comprises performing the plasma process at a cyclic electrical power in the range of 50 W-200 W and at a cyclic frequency in the range of 40 KHz-1 MHz.

In another aspect of the disclosure, a method for forming a bonded structure comprises direct bonding the semiconductor-containing bonding layer formed on the semiconductor substrate to the second semiconductor element.

In some embodiments, the semiconductor substrate comprises silicon, and a second semiconductor substrate of the second semiconductor element also comprises silicon. Direct bonding the semiconductor-containing bonding layer to the second semiconductor element comprises direct bonding the semiconductor-containing bonding layer to the second semiconductor substrate.

In some embodiments, the method further comprises forming a dielectric bonding layer over the second semiconductor substrate of the second semiconductor element. Furthermore, direct bonding the semiconductor-containing bonding layer to the second semiconductor element comprises direct bonding the semiconductor-containing bonding layer to the dielectric bonding layer.

In some embodiments, the method further comprises forming a second semiconductor-containing bonding layer over the second semiconductor substrate of the second semiconductor element. Furthermore, direct bonding the semiconductor-containing bonding layer to the second semiconductor element comprises direct bonding the semiconductor-containing bonding layer to the second semiconductor-containing bonding layer.

In another aspect, method for forming a bonded structure comprises providing a first semiconductor element having a base substrate layer comprising a semiconductor material, forming a first bonding layer comprising a semiconductor-containing oxynitride material over the base substrate layer, where the first bonding layer has a thickness in the range of 0.5 nm-10 nm and has a first bonding surface, providing a second semiconductor element having a second bonding surface, and directly bonding the first bonding surface of the first semiconductor element to the second bonding surface of the second semiconductor element.

In some embodiments, forming the first bonding layer comprises exposing an upper surface of the first semiconductor element to a nitrogen and oxygen containing plasma. In some embodiments, exposing an upper surface of the first semiconductor element to a nitrogen and oxygen containing plasma comprises exposing the upper surface of the first semiconductor element to products of a remote plasma system. In some embodiments, exposing an upper surface of the first semiconductor element to a nitrogen and oxygen containing plasma comprising exposing the upper surface of the first semiconductor substrate to products of an in situ plasma system.

In some embodiments, method for forming a bonded structure further comprises forming a second bonding layer over a base substrate layer of the second semiconductor element, where the base substrate layer of the second semiconductor element comprises a semiconductor material. In some embodiments, the second bonding layer comprises semiconductor-containing oxynitride material. In some embodiments, the second bonding layer comprises dielectric material. In some embodiments, the dielectric material is an oxide material.

In some embodiments, method for forming a bonded structure further comprises annealing the bonded structure at a temperature in the range of 100° C.-300° C. for a duration of 10 minutes to 1 hour. In some embodiments, the annealing is at a temperature in the range of 150° C.-250° C. for a duration of 15 minutes to 30 minutes.

In another aspect, a directly bonded structure comprises a first element having a first substrate layer comprising a semiconductor material, a second element having a second substrate layer comprising a semiconductor material, and a semiconductor-containing oxynitride layer disposed between the first substrate layer and the second substrate layer, where the thickness of semiconductor-containing oxynitride layer is in the range of 0.5 nm-10 nm. In some embodiments, the thickness of the semiconductor-containing oxynitride layer is in the range of 2 nm-6 nm.

In some embodiments, the semiconductor material of the first substrate layer and the semiconductor material of second substrate layer comprise the same semiconductor material. In some embodiments, the semiconductor material of the first substrate layer and the semiconductor material of second substrate layer comprise different semiconductor materials.

In some embodiments, the directly bonded structure further comprises a dielectric bonding layer disposed between the semiconductor-containing oxynitride layer and the second substrate layer. In some embodiments, the dielectric bonding layer comprises an oxide material.

In another aspect, a bonded structure comprises a first microelectronic element having a first bonding layer comprising semiconductor-containing oxynitride and a first bonding surface, where the first bonding layer has a thickness in the range of 0.5 nm-10 nm, a second microelectronic element having a second bonding surface, where the first bonding surface is direct bonded to the second bonding surface without an intervening adhesive.

In some embodiments, the first microelectronic element comprises a base substrate having silicon. In some embodiments, the second microelectronic element comprise a second bonding layer comprising semiconductor-containing oxynitride.

In some embodiments, the bonded structure further comprises a dielectric bonding layer forming a part of the second microelectronic element and bonded to the first bonding layer.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method for forming a bonding layer on an upper surface of a semiconductor substrate, the method comprising:
exposing the upper surface of the semiconductor substrate to products of at least one plasma containing nitrogen and oxygen to form a semiconductor-containing oxynitride layer on the upper surface of the semiconductor substrate; and
preparing the upper surface for direct bonding to a semiconductor element, the preparing the upper surface comprising planarizing the upper surface.

2. The method of claim 1, wherein the semiconductor substrate comprises bare silicon.

3. The method of claim 1, wherein the semiconductor-containing oxynitride layer comprises silicon oxynitride.

4. The method of claim 1, wherein exposing the upper surface of the semiconductor substrate to products of at least one plasma comprises exposing the upper surface of the semiconductor substrate to products of a remote plasma system.

5. The method of claim 1, wherein exposing the upper surface of the semiconductor substrate to products of at least one plasma comprises exposing the upper surface of the semiconductor substrate to products of an in situ plasma system.

6. The method of claim 1, wherein exposing the upper surface of the semiconductor substrate to products of at least one plasma comprises flowing the products of a plasma containing nitrogen and/or oxygen over the upper surface of the semiconductor at a flow rate of about 50 sccm to 200 sccm nitrogen and/or about 10 sccm to 50 sccm oxygen, wherein when the plasma contains both nitrogen and oxygen a ratio of nitrogen flow rate to oxygen flow rate ranges from 1:1 to 10:1.

7. The method of claim 1, wherein exposing the upper surface of the semiconductor substrate to products of at least one plasma comprises performing the plasma process at a temperature in the range of 100° C.-300° C.

8. (canceled)

9. The method of claim 1, wherein exposing the upper surface of the semiconductor substrate to products of at least one plasma comprises performing the plasma process at a pressure in the range of 0.5-2 Torr.

10. The method of claim 1, wherein exposing the upper surface of the semiconductor substrate to products of at least one plasma comprises performing the plasma process at a cyclic electrical power in the range of 50 W-200 W and at a cyclic frequency in the range of 40 KHz-1 MHz.

11. A method for forming a bonded structure, comprising:
direct bonding the semiconductor-containing bonding layer formed on the semiconductor substrate according to the method of claim 1 to a second semiconductor element.

12. The method of claim 11, wherein the semiconductor substrate comprises silicon, wherein a second semiconductor substrate of the second semiconductor element comprises silicon, and wherein direct bonding the semiconductor-containing bonding layer to the second semiconductor element comprises direct bonding the semiconductor-containing bonding layer to the second semiconductor substrate.

13. The method of claim 11, further comprising:
forming a dielectric bonding layer over the second semiconductor substrate of the second semiconductor element; and
wherein direct bonding the semiconductor-containing bonding layer to the second semiconductor element comprises direct bonding the semiconductor-containing bonding layer to the dielectric bonding layer.

14. The method of claim 11, further comprising:
forming a second semiconductor-containing bonding layer over the second semiconductor substrate of the second semiconductor element by exposing an upper surface of the second semiconductor substrate to products of at least one plasma containing nitrogen and oxygen; and
wherein direct bonding the semiconductor-containing bonding layer to the second semiconductor element comprises direct bonding the semiconductor-containing bonding layer to the second semiconductor-containing bonding layer.

15. A method for forming a bonded structure, comprising:
providing a first semiconductor element having a base substrate layer comprising a semiconductor material;
forming a first bonding layer comprising a semiconductor-containing oxynitride material over the base substrate layer, the first bonding layer having a thickness in the range of 0.5 nm-10 nm, the first bonding layer having a first bonding surface;
providing a second semiconductor element having a second bonding surface; and
directly bonding the first bonding surface of the first semiconductor element to the second bonding surface of the second semiconductor element.

16. The method of claim 15, wherein forming the first bonding layer comprises exposing an upper surface of the first semiconductor element to a nitrogen and oxygen containing plasma.

17.-18. (canceled)

19. The method of claim 15, further comprising forming a second bonding layer over a base substrate layer of the second semiconductor element, the base substrate layer of the second semiconductor element comprising a semiconductor material.

20. The method of claim 19, wherein the second bonding layer comprises semiconductor-containing oxynitride material.

21. The method of claim 19, wherein the second bonding layer comprises dielectric material.

22. The method of claim 21, wherein the dielectric material is an oxide material.

23. The method of claim 15, further comprising:
annealing the bonded structure at a temperature in the range of 100° C.-300° C. for a duration of 10 minutes to 1 hour.

24. The method of claim 23, wherein the annealing the bonded structure comprises a temperature in the range of 150° C.-250° C. for a duration of 15 minutes to 30 minutes.

25.-34. (canceled)
